(19) United States
(12) Patent Application Publication
(10) Pub. No.: US 2017/0351069 A1
(43) Pub. Date: Dec. 7, 2017

(54) ELECTRONIC COMPONENT MOUNTING PACKAGE AND ELECTRONIC DEVICE

(71) Applicant: KYOCERA Corporation, Kyoto-shi, Kyoto (JP)

(72) Inventors: Hiroshi YAMADA, Satsumasendai-shi (JP); Takuji OKAMURA, Satsumasendai-shi (JP); Akihiko FUNAHASHI, Kagoshima-shi (JP)

(21) Appl. No.: 15/536,519

(22) PCT Filed: Oct. 27, 2015
(86) PCT No.: PCT/JP2015/080212

§ 371 Date: Jun. 15, 2017

(30) Foreign Application Priority Data
Dec. 17, 2014 (JP) 2014-255248

(51) Int. Cl. G02B 13/18; H01L 27/146; H04N 5/225; H04N 5/335

(52) U.S. Cl. CPC G02B 13/18; H04N 5/335; H01L 27/14625; H04N 5/225

(57) ABSTRACT

Provided are an electronic component mounting package and an electronic device capable of making heat distribution of a curved electronic component mounting portion uniform. The electronic component mounting package (1) includes: a substrate (2) including a first main surface and a second main surface, and one of a recessed portion (2d) and a convex portion (2e) that is arc-shaped in a vertical cross-sectional view and that is provided in the first main surface; and a curved electronic component mounting portion (11), which is provided in the one of the recessed portion (2d) and the convex portion (2e) and on which the bent curved electronic component (10) is mounted. The substrate (2) has a notch (4) in the second main surface such that the notch (4) overlaps with the curved electronic component mounting portion (11) when the substrate (2) is viewed in a plane perspective from the first main surface side.

### TECHNICAL FIELD

The present invention relates to an electronic component mounting package on which is mounted a curved electronic component, which includes an imaging device such as a charge coupled device (CCD) or a complementary metal oxide semiconductor (CMOS), a light emitting element such as a light emitting diode (LED) and the like, and to an electronic device.

### BACKGROUND ART

An imaging device having a curved shape is conventionally known (as in Japanese Unexamined Patent Application Publication No. 2004-356175A, for example). Note that here, a package for mounting an imaging device is the electronic component mounting package, and the electronic device includes the electronic component mounting package and the imaging device.

With respect to the above-mentioned electronic component mounting package, there is a risk that a significant local difference in heat distribution of the curved imaging device may occur when the imaging device operates, resulting in a concern that the processing function of the electronic device may deteriorate.

### SUMMARY OF INVENTION

An electronic component mounting package according to an aspect of the present invention includes: a substrate including a first main surface and a second main surface, and one of a recessed portion and convex portion that is arc-shaped in a vertical cross-sectional view and that is provided in the first main surface; and a curved electronic component mounting portion, which is provided in the one of the recessed portion and the convex portion and on which a bent curved electronic component is mounted. The substrate has a notch in the second main surface, and the notch overlaps with the curved electronic component mounting portion when the substrate is seen in a plane perspective from the first main surface side.

An electronic device according to an aspect of the present invention includes the above-described electronic component mounting package, and the curved electronic component mounted in the electronic component mounting package.

### BRIEF DESCRIPTION OF DRAWINGS

FIG. 1A is a top view illustrating an outer appearance of an electronic component mounting package and an electronic device according to a first embodiment of the present invention, and FIG. 1B is a vertical cross-sectional view corresponding to a line A-A in FIG. 1A.

FIG. 2A is an exterior perspective view of the electronic component mounting package according to the first embodiment of the present invention, and FIG. 2B is a modified example of FIG. 2A.

FIG. 3A is a top view illustrating an outer appearance of the electronic component mounting package and the electronic device according to a second embodiment of the present invention, and FIG. 3B is a vertical cross-sectional view corresponding to a line A-A in FIG. 3A.

FIG. 4A is a top view illustrating an outer appearance of the electronic component mounting package and the electronic device according to a third embodiment of the present invention, and FIG. 4B is a vertical cross-sectional view corresponding to a line A-A in FIG. 4A.

FIG. 5 is a vertical cross-sectional view illustrating an outer appearance of the electronic component mounting package and the electronic device according to a fourth embodiment of the present invention.

FIG. 6A is a top view illustrating an outer appearance of the electronic component mounting package and the electronic device according to a fifth embodiment of the present invention, and FIG. 6B is a vertical cross-sectional view corresponding to a line A-A in FIG. 6A.

FIG. 7A is a top view illustrating an outer appearance of the electronic component mounting package and the electronic device according to a sixth embodiment of the present invention, and FIG. 7B is a vertical cross-sectional view corresponding to a line A-A in FIG. 7A.

FIG. 8A is a top view illustrating an outer appearance of the electronic component mounting package and the electronic device according to a seventh embodiment of the present invention, and FIG. 8B is a vertical cross-sectional view corresponding to a line A-A in FIG. 8A.

FIG. 9 is a vertical cross-sectional view illustrating an outer appearance of the electronic component mounting package and the electronic device according to an eighth embodiment of the present invention.

FIG. 10 is a vertical cross-sectional view illustrating an outer appearance of the electronic component mounting package and the electronic device according to a ninth embodiment of the present invention.

FIG. 11 is a vertical cross-sectional view illustrating an outer appearance of the electronic component mounting package and the electronic device according to another mode of the ninth embodiment of the present invention.

### DESCRIPTION OF EMBODIMENTS

Several exemplary embodiments of the present invention will be described hereinafter with reference to the drawings. Note that, in the following description, an electronic component mounting package includes an electronic component mounting package having a plurality of curved electronic component mounting portions. Further, an electronic device has a configuration in which a curved electronic component is mounted on the electronic component mounting package. Any direction may be defined as upward or downward for the electronic component mounting package and the electronic device, but for the sake of convenience, an xyz orthogonal coordinate system will be used here, with a positive side in the z direction being defined as upward and the terms “top surface” and “bottom surface” being used.

### First Embodiment

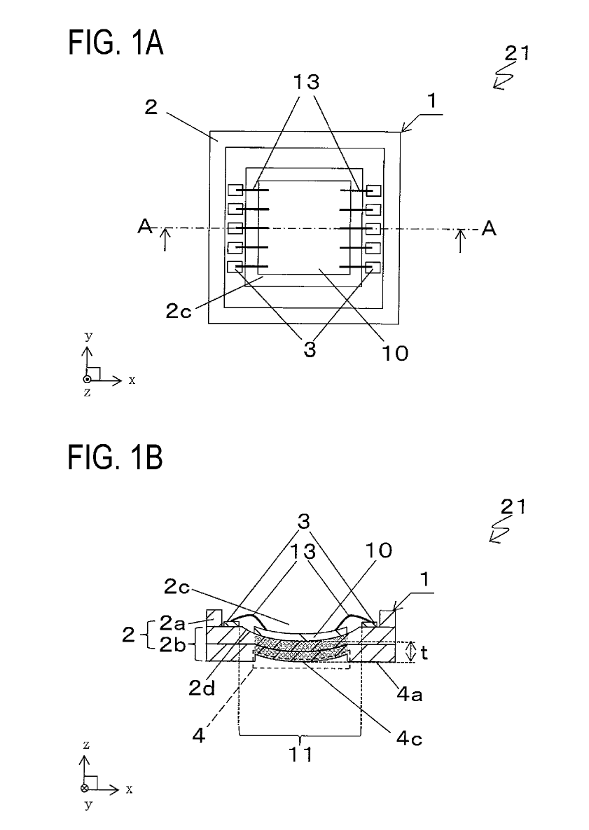

An electronic device 21 and an electronic component mounting package 1 according to a first embodiment of the present invention will be described with reference to FIGS. 1A and 1B. The electronic device 21 according to the present embodiment has the electronic component mounting package 1 and a curved electronic component 10.

As illustrated in FIGS. 1A and 1B, the electronic component mounting package 1 includes: a substrate 2 including a first main surface and a second main surface, and a recessed portion 2d that is arc-shaped in a vertical cross-sectional view and that is provided in the first main surface; and a curved electronic component mounting portion 11, which is provided in the recessed portion 2d and on which the bent curved electronic component 10 is mounted. The substrate 2 has a notch 4 in the second main surface, which overlaps with the curved electronic component mounting portion 11 when the substrate 2 is viewed in a plane perspective from the first main surface side.

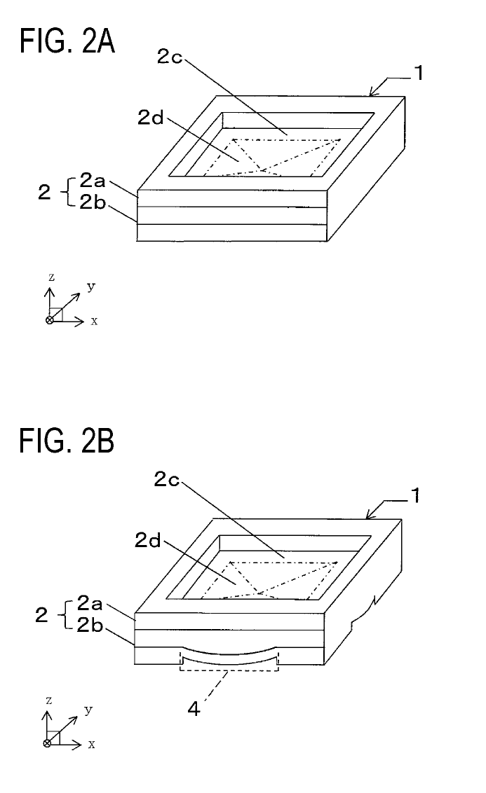

In examples illustrated in FIGS. 1A and 1B and in FIGS. 2A and 2B, the substrate 2 has a main surface and the recessed portion 2d provided in the first main surface. Further, in the example illustrated in FIGS. 1A and 1B, curved electronic component connection pads 3 are provided on the first main surface of the substrate 2. Note that the curved electronic component connection pads 3 and the curved electronic component 10 are omitted in FIGS. 2A and 2B. FIG. 2A is the electronic component mounting package 1 in which the notch 4 cannot be seen from the side surface, and FIG. 2B is the electronic component mounting package 1 in which the notch 4 can be seen from the side surface.

The substrate 2 is configured by a wiring conductor (to be described later) being formed on an insulating substrate. As a material for the insulating substrate, an electrical insulating ceramic, resin or the like is used, for example.

Examples of the electrical insulating ceramic used as the material for the insulating substrate of the substrate 2 include an aluminum oxide-based sintered body, a mullite-based sintered body, a silicon carbide sintered body, an aluminum nitride-based sintered body, a silicon nitride-based sintered body, a glass ceramic sintered body, and the like.

Examples of the resin used as the material for the insulating substrate of the substrate 2 include an epoxy resin, a polyimide resin, an acrylic resin, a phenol resin, a fluorine-based resin, and the like. The fluorine-based resin includes a polyester resin, an ethylene tetrafluoride resin, for example.

As illustrated in FIGS. 1A and 1B, the substrate 2 is formed by a plurality of insulating layers made from the above-described material being layered in the up-down direction.

The substrate 2 may be formed of three layers of the insulating layers as in the examples illustrated in FIGS. 1A and 1B and in FIGS. 2A and 2B, or may be formed of a single layer to two layers, or of four or more layers of the insulating layers. In the examples illustrated in FIGS. 1A and 1B, and FIGS. 2A and 2B, the substrate 2 is formed of the three layers of the insulating layers.

An external circuit connection electrode may be provided on the top surface, a side surface, or the bottom surface of the substrate 2. The external circuit connection electrode is provided, for example, to electrically connect the electronic device 21 to an external device and the like.

The interior of the substrate 2 may be provided with a wiring conductor, which is formed of through conductors that cause conduction between each of the insulating layers and internal wiring, and the substrate 2 may have a wiring conductor that is exposed at the surface of the substrate 2. Further, the external circuit connection electrode and the curved electronic component connection pads 3 may be in electrically communication by the wiring conductor. In addition, the wiring conductor provided inside a frame body 2a forming the substrate 2 may be in electrical communication by the wiring conductor exposed at the surface of the frame body 2a and the like.

When the substrate 2 is formed of the electrical insulating ceramic, the curved electronic component connection pads 3, the external circuit connection electrode, and the wiring conductor are formed of one of tungsten (W), molybdenum (Mo), manganese (Mn), silver (Ag), and copper (Cu), or from an alloy and the like containing at least one type of metal material selected from among these. When the substrate 2 is formed of the resin, the curved electronic component connection pads 3, the external circuit connection electrode, and the wiring conductor are formed of one of copper (Cu), gold (Au), aluminum (Al), nickel (Ni), chromium (Cr), molybdenum (Mo), and titanium (Ti), or are formed from an alloy and the like containing at least one type of metal material selected from among these.

A plating layer is preferably provided on the surface at which the curved electronic component connection pads 3, the external circuit connection electrode, and the wiring conductor are exposed. According to this configuration, the surface at which the curved electronic component connection pads 3, the external circuit connection electrode, and the wiring conductor are exposed is protected and oxidation can be inhibited. Further, according to this configuration, electrical connectivity between the curved electronic component connection pads 3 and the curved electronic component 10 via connecting members 13 (wire bonding and the like) can be favorably secured. As the plating layer, an Ni plating layer with a thickness of 0.5 to 10 μm is deposited. In addition, a gold (Au) plating layer with a thickness of 0.5 to 3 μm may be deposited on top of the Ni plating layer.

As illustrated in the example in FIGS. 1A and 1B, in the recessed portion 2d, the electronic component mounting package 1 has the curved electronic component mounting portion 11, on which the bent curved electronic component 10 is mounted.

The curved electronic component mounting portion 11 refers to an area in which the curved electronic component 10 is mounted. In the example illustrated in FIGS. 1A and 1B, the curved electronic component mounting portion 11 is an area further to the inside than the curved electronic component connection pads 3. In FIGS. 1A and 1B, the curved electronic component mounting portion 11 is an area that is recessed in an arc shape in a cross-sectional view.

In the example illustrated in FIGS. 1A and 1B, the substrate 2 of the electronic component mounting package 1 has the notch 4 in the second main surface, which overlaps with the curved electronic component mounting portion 11 when the substrate 2 is viewed in a plane perspective from the first main surface side.

As illustrated in FIGS. 1A and 1B, because the substrate 2 has the notch 4 in the second main surface, which overlaps with the curved electronic component mounting portion 11 when the substrate 2 is viewed in a plane perspective from the first main surface side, when the curved electronic component 10 is mounted in the electronic component mounting package 1 and the curved electronic component 10 operates and generates heat, by having the notch, the thickness of the substrate 2 can be made appropriate in accordance with a heat generation location of the curved electronic component 10. Thus, the heat radiation of the curved electronic component 10 can be optimized, and the heat distribution of the curved electronic component mounting portion 11 can be made uniform. Note that, by changing the position and the size of the notch 4, for example, heat transmitted to the space (the air) of the notch 4 and transmitted through contact with an external circuit and the like can be optimized, and the heat distribution of the curved electronic component mounting portion 11 and be made even more uniform.

Further, in general, by the curved electronic component mounting portion being formed as the arc-shaped recessed portion, the behavior or the direction of stress resulting from thermal expansion or thermal shrinkage are different for the curved electronic component mounting portion and for a flat portion surrounding the curved electronic component mounting portion. Therefore, a boundary between the curved electronic component mounting portion and the flat portion surrounding the curved electronic component mounting portion are subject to stress, and there are concerns that deformation, cracks, or breaks of the substrate may occur. As illustrated in FIGS. 1A and 1B, by the substrate 2 having the notch 4 in the second main surface, which overlaps with the curved electronic component mounting portion 11 when the substrate 2 is viewed in a plane perspective from the first main surface side, even when the thermal expansion or the thermal shrinkage of the electronic component mounting package 1 occurs when the curved electronic component 10 operates and generates heat, since the substrate 2 has the notch 4, the stress of the thermal expansion or the thermal shrinkage from the curved electronic component mounting portion 11 can be alleviated and absorbed. Thus, stress acting on a boundary between the curved electronic component mounting portion 11 and the flat portion 11a surrounding the curved electronic component mounting portion 11 can be reduced, and deformation, cracks, or breaks of the substrate 2 can thus be reduced.

Further, a thickness t of the curved electronic component mounting portion 11 that overlaps the notch 4 in a plan view is 50 μm or greater. This is preferable in that a rise in the temperature of the substrate 2 directly below the curved electronic component mounting portion 11 is suppressed, while the heat distribution of the curved electronic component mounting portion 11 is easily made uniform. Note that when the substrate 2 is formed from two layers, as in FIGS. 1A and 1B, at least one layer is preferably 50 μm or greater.

Further, in a cross-sectional view, a distance from a peripheral edge of the recessed portion 2d of the substrate 2 to a lowest point 4c is preferably 30 μm or greater. Since, in a cross-sectional view, the distance from the peripheral edge of the recessed portion 2d of the substrate 2 to the lowest point 4c is 30 μm or greater, in a step of mounting the curved electronic component 10, the curved electronic component 10 is easily mounted in the center of the recessed portion 2d. Furthermore, when the curved electronic component 10 is the imaging device, a curvature of the recessed portion 2d is preferably equal to or less than a curvature of a concave lens or a convex lens provided on a bottom-most surface side of a lens housing that is bonded to the electronic device 21. When the curvature of the recessed portion 2d is equal to the curvature of the concave lens or the convex lens provided on the bottom-most surface side of the lens housing, a more favorable image can be obtained. Further, since the curvature of the recessed portion 2d is equal to or less than the curvature of the concave lens or the convex lens provided on the bottom-most surface side of the lens housing, in the step of mounting the curved electronic component 10, bonding can be performed without placing any load on the curved electronic component 10.

Further, in the example illustrated in FIGS. 1A and 1B, the lowest point 4c of the notch 4 of the electronic component mounting package 1 is positioned at the same height as the bottom surface of the substrate 2 in a vertical cross-sectional view. In this way, the arc-shaped section of the notch 4 comes into contact with the external circuit and the like, thus optimizing the heat radiation of the curved electronic component 10. As a result, the heat distribution of the curved electronic component mounting portion 11 is easily made even more uniform. Further, when the external circuit and the like and the electronic device 21 are mounted, the lowest point 4c of the notch 4 is bonded to the external circuit using an adhesive and the like made from resin and the like, and thus the thermal expansion of the substrate 2 resulting from heat generation during the operation of the curved electronic component 10 can be suppressed. As a result, the stress acting on the boundary between the curved electronic component mounting portion 11 and the flat portion 11a surrounding the curved electronic component mounting portion 11 can be reduced. Note that, as will be described later, the lowest point 4c of the notch 4 of the electronic component mounting package 1 may be positioned at a height that is higher than the bottom surface of the substrate 2 in a vertical cross-sectional view. Note also that, the “same height” refers to the fact that a difference between the height position of the lowest point 4c of the notch 4 and the height position of the bottom surface of the substrate 2 is 200 μm or less.

Note further that, as illustrated in FIGS. 1A and 1B, the lowest point 4c of the notch 4 is a section of the inner surface (the bottom surface) of the notch 4 that is closest to the bottom surface side of the substrate 2.

In addition, the substrate 2 of the electronic component mounting package 1 may have a section (illustrated by a shaded section, and also illustrated in the same manner in embodiments to be described later) with a constant thickness between the recessed portion 2d and the notch 4. In this way, the heat distribution of the section having the constant thickness can be made even more uniform. Further, by having a section in which the thickness of the substrate 2 directly below the curved electronic component mounting portion 11 is thicker, heat diffused to the location of the substrate 2 with the constant thickness can be reduced, and thus the heat distribution can be effectively made more uniform. Note that the section with the constant thickness refers to the fact that a difference between a thick location and a thin location in the shaded section is 50 μm or less, or is no greater than 1% of the thickness of the thick location.

In addition, with respect to the substrate 2 of the electronic component mounting package 1, the thickness, when the substrate 2 is viewed in a plane perspective from the first main surface side, between the section that overlaps with the notch 4 of the recessed portion 2d and the notch 4 as a whole is preferably constant. As a result, the heat distribution of the section that overlaps with the notch 4 in a plan view is made uniform, and thus, the heat distribution of the curved electronic component 10 as a whole can be made more uniform. Further, by making the thickness constant over a wide section of the recessed portion 2d in a vertical cross-sectional view, during heat generation when the curved electronic component 10 operates, the behavior of the thermal expansion is constant. Thus, stress acting on the boundary between the curved electronic component mounting portion 11 and the flat portion 11a surrounding the curved electronic component mounting portion 11 can be reduced, and deformation, cracks, or breaks of the substrate 2 can be further reduced.

In addition, the peripheral edge of the recessed portion 2d may be a rectangular shape in a plan view as illustrated in the example in FIGS. 1A and 1B, but may also be a circular shape in a plan view. Further, when the shape of the peripheral edge of the recessed portion 2d has one or more corner portions in a plan view, by causing each of edges connecting the corner portions not to be a straight line but to draw a gently curved line, stress acting on the curved electronic component 10 when mounting the curved electronic component 10 can be reduced.

Further, an angle θ formed between the side surfaces of the recessed portion 2d and extended surfaces of the flat portion 11a provided around the recessed portion 2d is less than 90°.

In the example illustrated in FIGS. 1A and 1B, the substrate 2 is formed from one type of material. In addition, the substrate 2 of the electronic component mounting package 1 to be described later may be configured by the frame body 2a and a base portion 2b provided on the bottom surface of the frame body 2a. In this case, the material used in the frame body 2a is, for example, one of an electrical insulating ceramic, a resin and the like, and the material used in the base body 2b is, for example, one of an electrical insulating ceramic, a resin, and a metal. Further, the frame body 2a and the base portion 2b may be provided with a wiring conductor, which is formed of through conductors that cause conduction between each of the insulating layers and internal wiring, and may have a wiring conductor that is exposed at the surface. In addition, at this time, the frame body 2a and the base portion 2b may be in electrical communication.

Next, the electronic device 21 will be described with reference to FIGS. 1A and 1B. In the example illustrated in FIGS. 1A and 1B, the electronic device 21 has the electronic component mounting package 1 and the curved electronic component 10 mounted on the curved electronic component mounting portion 11.

An imaging device, such as a CCD type imaging device or a CMOS type imaging device, a light emitting element such as an LED, or a semiconductor circuit element or the like is used as the curved electronic component 10, for example. In the example illustrated in FIGS. 1A and 1B, each of electrodes of the curved electronic component 10 are in electrical communication with the curved electronic component connection pads 3 using the connecting members 13 (bonding wires).

Note that, although not illustrated, the bottom surface of the curved electronic component 10 and the curved electronic component mounting portion 11 of the substrate 2 are bonded using a thermosetting resin and the like, for example, and the curved electronic component 10 is thus firmly mounted. Positional displacement of the curved electronic component 10 during handling and the like can thus be reduced. In addition, in the step of mounting the curved electronic component 10, because the above-described thermosetting resin and the like is interposed between the bottom surface of the curved electronic component 10 and the curved electronic component mounting portion 11 of the substrate 2, the occurrence of dust and the like resulting from rubbing between the substrate and the curved electronic component 10 when adjusting the mounting location and the inclination can be reduced.

Since the electronic device 21 according the present embodiment of the present invention has the electronic component mounting package 1 and the curved electronic component 10 mounted in the curved electronic component mounting portion 11 of the above-described configuration, the heat radiation of the curved electronic component 10 can be optimized, and the heat distribution of the curved electronic component mounting portion 11 can be made uniform. Further, the stress acting on the boundary between the curved electronic component mounting portion 11 and the flat portion 11a surrounding the curved electronic component mounting portion 11 can be reduced, and deformation, cracks, or breaks of the substrate 2 can be reduced.

Next, an example of a manufacturing method of the electronic component mounting package 1 according to the present embodiment will be described.

Note that the example of the manufacturing method described below is a manufacturing method that uses a multipiece wiring base plate.

(1) First, ceramic green sheets that configure the substrate 2 are formed. For example, in the case of obtaining the substrate 2 that is an aluminum oxide (Al₂O₃)-based sintered body, a powder such as silica (SiO₂), magnesia (MgO), calcia (CaO) is added as a sintering aid to the Al₂O₃ powder. A suitable binder, a solvent, and a plasticizer are furthermore added, and the mixture is kneaded together into a slurry. Then, multipiece ceramic green sheets are obtained through a conventionally well known formation method, such as a doctor blade method, and a calender roll method.

Note that when the substrate 2 is formed from a resin, for example, the substrate 2 can be formed through a method such as a transfer mold method or an injection mold method, using a mold that enables the resin to be formed into a predetermined shape.

Meanwhile, the substrate 2 may be formed by impregnating a base material formed of glass fibers with a resin, such as glass epoxy resin. In this case, the substrate 2 can be formed by impregnating a base material formed of glass fibers with an epoxy resin precursor and thermally curing the epoxy resin precursor at a predetermined temperature.

(2) Next, using a screen printing method, a metal paste is coated on or filled into a section of the ceramic green sheet obtained in the above-described step (1) that will become the curved electronic component connection pads 3, the external circuit connection electrodes and the wiring conductor including the through conductor and the internal wiring.

This metal paste is created so as to have an appropriate viscosity by adding a suitable solvent and binder to the metal powder formed of the above-described metal materials, and kneading the mixture. Note that glass, ceramics, and the like may also be included in the metal paste in order to increase the bonding strength with the substrate 2.

(3) Next, the ceramic green sheets are prepared that will form the substrate 2 having the recessed portion 2d. In order to manufacture the substrate 2 having the recessed portion 2d, the ceramic green sheets that will form the frame body 2a and the base portion 2b are prepared, for example. Then, through a step in which the plurality of ceramic green sheets are laminated and compressed, the plurality of ceramic green sheets are integrated with each other. For example, the ceramic green sheet that forms the frame body 2a can be formed using one of a metal mold and laser processing to stamp out a section forming an opening 2c. Alternatively, the plurality of ceramic green sheets may first be laminated and compressed and the section forming the opening 2c may then be stamped out from the ceramic green sheet laminated body.

The arc-shaped recessed portion 2d and the notch 4 can be formed in the step of forming the base portion 2b. For example, in the step of forming the base portion 2b using the normal metal mold, after the ceramic green sheet that will form the base portion 2b has been prepared, the recessed portion 2d and the notch 4 may be formed through pressing using a metal mold having the shape of the arc-shaped recessed portion 2d or the notch 4. Alternatively, the recessed portion 2d or the notch 4 may be formed by cut processing, for example.

(4) Next, the ceramic green sheet laminated body that will form the substrate 2 is created by laminating and compressing the ceramic green sheets that serve as each insulation layer. At this time, the ceramic green sheet laminated body that will form the integrated substrate 2 can be created by laminating and compressing the ceramic green sheet that serves as the above-described frame body 2a and the ceramic green sheet that serves as the above-described base portion 2b.

(5) Next, the ceramic green sheet laminated body is fired at a temperature of approximately 1500 to 1800° C. to obtain a multipiece wiring board on which a plurality of the substrates 2 are arranged. Note that, in this step, the above-described metal paste is fired at the same time as the ceramic green sheets forming the substrate 2, and forms the curved electronic component connection pads 3, the external circuit connection electrodes, or the wiring conductor.

(6) Next, the multipiece wiring board obtained by the firing is divided into the plurality of substrates 2. In this division, a method can be used in which split grooves are formed in the multipiece wiring board in locations that will serve as the outer edges of the substrates 2, and the multipiece wiring board is then divided along those split grooves. Alternatively, a method can be used in which the multipiece wiring board is cut, by slicing and the like, along the locations that will serve as the outer edges of the substrates 2. The split grooves can be formed by forming cuts in the multipiece wiring board at a depth less than the thickness of the multipiece wiring board using a slicing device after the firing, or the split grooves may be formed by pressing a cutter blade against the ceramic green sheet laminated body used as the multipiece wiring board, or by forming cuts using a slicing device at a depth less than the thickness of the ceramic green sheet laminated body. Note that the substrates 2 can be created in a state in which f the recessed portion 2d or the notch 4 is not formed, and the recessed portion 2d or the notch 4 can be formed by cut processing after the division into the plurality of substrates 2.

By the above-described steps (1) to (6), the electronic component mounting package 1 is obtained. Note that an order of the above-described steps (1) to (6) is not prescribed. By mounting the curved electronic component 10 in the curved electronic component mounting portion 11 of the electronic component mounting package 1 formed in this way, the electronic device 21 can be created.

### Second Embodiment

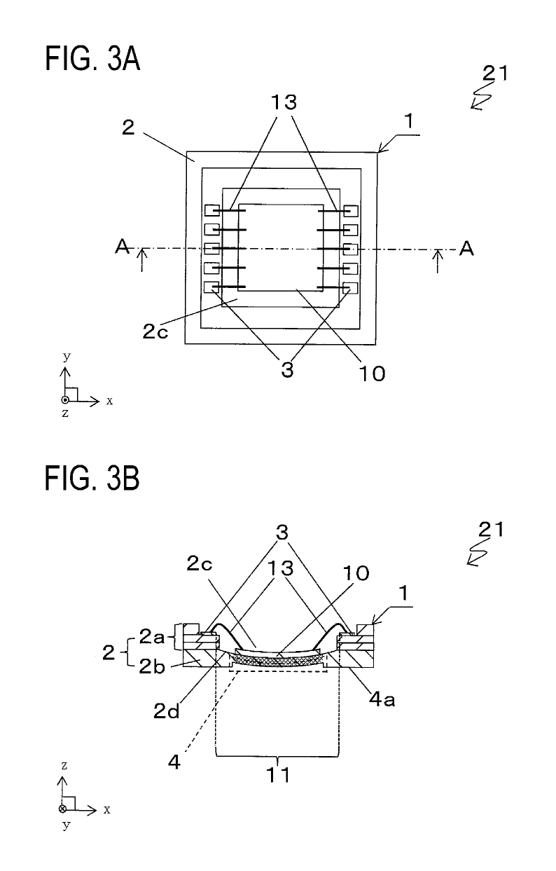

The electronic component mounting package 1 and the electronic device 21 according to a second embodiment of the present invention will be described next with reference to FIGS. 3A and 3B.

In the electronic device 21 according to the present embodiment, a point of difference with the electronic device 21 according to the first embodiment is that the substrate 2 is formed of the frame body 2a and the base portion 2b made from a different material to the frame body 2a.

In the example illustrated in FIGS. 3A and 3B, the substrate 2 is configured by the frame body 2a and the base portion 2b provided on the bottom surface of the frame body 2a, and the base portion 2b is made from a metal material. In this way, in general, compared to a case in which the base portion 2b is made from the same electrical insulating ceramic, resin and the like as the frame body 2a, the base portion 2b made from the metal material has a higher thermal conductivity. Thus, the heat distribution of the curved electronic component mounting portion 11 can be made uniform at an earlier stage.

Further, compared to the case in which the base portion 2b is made from the same electrical insulating ceramic, resin and the like as the frame body 2a, when the base portion 2b is made from the metal material, ductility is increased. Thus, even when the thermal expansion or the thermal shrinkage of the electronic component mounting package 1 occurs when the curved electronic component 10 operates and generates heat, the stress of the thermal expansion or the thermal shrinkage from the curved electronic component mounting portion 11 can be more favorably alleviated and absorbed. Thus, the stress acting on the boundary between the curved electronic component mounting portion 11 and the flat portion 11a surrounding the curved electronic component mounting portion 11 can be reduced, and deformation, cracks, or breaks of the substrate 2 can be reduced.

In addition, when the base portion 2b is made from the metal material, in a plan view, the curved electronic component 10 is positioned more to the inside than the periphery of the recessed portion 2d, and thus, when the curved electronic component 10 is the imaging device, for example, the base portion 2b can reduce an amount of diffused reflected light reaching a light receiving surface of the imaging device. Note that at this time, for example, black nickel and the like can be coated on the first main surface of the recessed portion 2d, and thus the amount of diffused reflected light reaching the light receiving surface can be reduced even more.

Here, when the base portion 2b is made from the metal material, the base portion 2b may be made from one of stainless steel (SUS), an Fe—Ni—Co alloy, 42 alloy, copper (Cu), a copper alloy, and the like. Further, the material used for the frame body 2a includes the electrical insulating ceramic, the resin and the like, for example. Further, for example, when the primary component of the frame body 2a is the aluminum oxide-based sintered body having a coefficient of thermal expansion of approximately 5×10⁻⁶/° C. to 10×10⁻⁶/° C., the base portion 2b is preferably stainless steel (SUS410) having a coefficient of thermal expansion of approximately 10×10⁻⁶/° C. In this case, a difference in thermal shrinkage or a difference in thermal expansion between the frame body 2a and the base portion 2b when the electronic device 21 operates is small, and thus, thermal stress acting on a bonding material bonding the frame body 2a and the base portion 2b can be alleviated, and peeling of the frame body 2a and the base portion 2b can be reduced.

A method for bonding the frame body 2a and the base portion 2b includes, for example, coating a paste type thermosetting resin (bonding member) on a bonding surface of one of the frame body 2a and the base portion 2b using the screen printing method, a dispensing method and the like, and drying the paste type thermosetting resin using one of a tunnel atmosphere furnace, an oven and the like. The method further includes, subsequently, causing to the frame body 2a and the base portion 2b that are overlaid with each other to pass through the one of the tunnel atmosphere furnace, the oven and the like in that state and, heating for approximately 90 minutes at approximately 150° C. to completely thermoset the bonding material, and to cause the frame body 2a and the base portion 2b to be firmly adhered to each other.

The base portion 2b is bonded to the frame body 2a by the bonding material made from one of a brazing material, the thermosetting resin, low melting point glass and the like. Further, the bonding material may be a material having conductivity, such as an anisotropic conduction film (ACF) and the like. The thermosetting resin used includes, for example, a bisphenol A based liquid epoxy resin and the like. As the bonding material, a material that does not deform as a result of heat generated during the mounting of or the operation of the curved electronic component 10 is preferably used, so that peeling of the frame body 2a and the base portion 2b can be favorably suppressed during the mounting of and the operation of the curved electronic component 10.

The bonding material is obtained, for example, by adding a filling material made from spherical silicon oxide and the like, a hardening agent mainly containing an acid anhydride such as tetrahydromethylphthalic anhydride, and carbon powder or the like as a coloring agent, to a main agent made from one of a bisphenol A based liquid epoxy resin, a bisphenol F based liquid epoxy resin, a liquid phenol novolac resin, and the like, and mixing and kneading these materials using a centrifugal agitator and the like, thus obtaining a paste.

Alternatively, for example, a bonding material can be used that is obtained by adding one of an imidazole or amine based hardening agent, a phosphorus based hardening agent, a hydrazine based hardening agent, an imidazole adduct based hardening agent, an amine adduct based hardening agent, a cationic polymerization based hardening agent, a dicyandiamide based hardening agent and the like to one of an epoxy resin, such as a bisphenol A based epoxy resin or a modified bisphenol A based epoxy resin, a bisphenol F based epoxy resin, a phenol novolac based epoxy resin, a cresol novolac based epoxy resin, a special novolac based epoxy resin, a phenol derivative epoxy resin, a bisphenol skeleton epoxy resin and the like.

A method for creating the arc-shaped recessed portion 2d of the base portion 2b may include, for example, pressing using a metal mold in the shape of an arc-shaped recess or a notch to form the recessed portion 2d. Alternatively, the method may include performing cut processing in a flat plate made from a metal material, for example to form the recessed portion 2d or the notch 4. Further, for example, the method may include etching to form the one of the recessed portion 2d or the notch 4. In addition, the method may further include a polishing step, after forming the recessed portion 2d, to reduce surface roughness.

### Third Embodiment

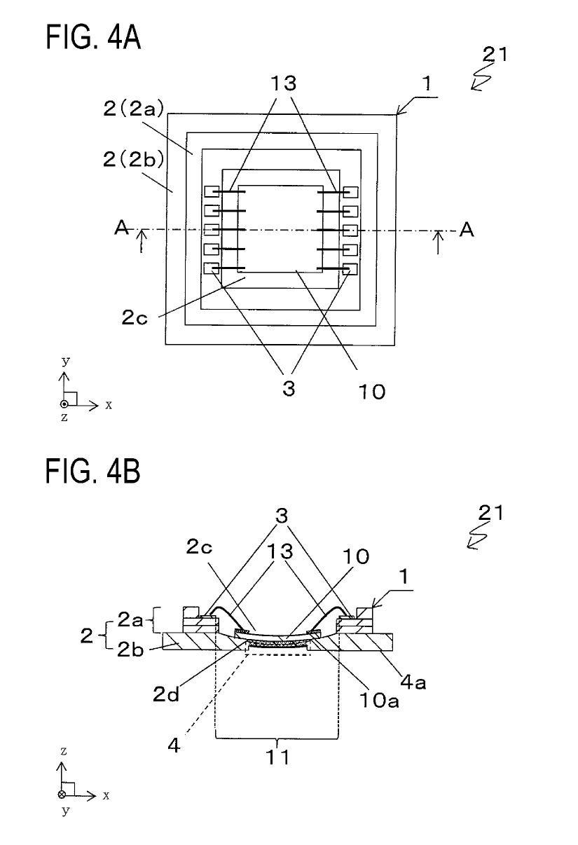

The electronic component mounting package 1 and the electronic device 21 according to a third embodiment of the present invention will be described next with reference to FIGS. 4A and 4B.

In the electronic device 21 according to the present embodiment, points of difference with the electronic device 21 according to the second embodiment are that a signal processing portion 10a is provided on the curved electronic component 10, a size of the notch 4 provided in the base portion 2b is different, and the base portion 2b protrudes further to the outer side than the frame body 2a in a plan view.

In an example illustrated in FIGS. 4A and 4B, the signal processing portion 10a is provided on an outer peripheral portion of the curved electronic component 10, and the notch 4 is provided in a position that does not overlap with the signal processing portion 10a in a plan view.

In general, when the curved electronic component 10 operates, a calorific value of the signal processing portion 10a is larger than in other portions. Thus, as illustrated in the example in FIGS. 4A and 4B, by providing the notch 4 in a position that does not overlap with the signal processing portion 10a in a plan view, the thickness of the substrate 2 directly below the signal processing portion 10a in a cross-sectional view can be made larger in comparison to the thickness of other portions of the substrate 2, which have a relatively small calorific value. As a result, the heat radiating properties of the signal processing portion 10a can be improved. Further, since the heat radiating properties of the signal processing portion 10a can be improved, the heat generated by the signal processing portion 10a is less easily transmitted to other locations of the curved electronic component 10, and thus the heat distribution in the other locations of the curved electronic component 10 can be more effectively made uniform.

Note that, here, when the curved electronic component 10 is the imaging device, the signal processing portion 10a includes a vertical drive circuit, a horizontal drive circuit, a column signal distance circuit, a system control circuit, an output circuit or the like, for example.

Further, in the example illustrated in FIGS. 4A and 4B, an outer peripheral portion of the base portion 2b is positioned further to the outer side than an outer peripheral portion of the frame body 2a in a plan view. As a result, the heat radiating properties of the signal processing portion 10a can be further improved. In addition, in the example illustrated in FIGS. 4A and 4B, the whole periphery of the base portion 2b is positioned further to the outer side than the outer periphery of the frame body 2a in a plan view, but the heat radiating properties of the signal processing portion 10a can be further improved by at least causing only the outer peripheral portion in the vicinity of the signal processing portion 10a to be positioned further to the outer side than the outer peripheral portion of the frame body 2a in a plan view.

### Fourth Embodiment

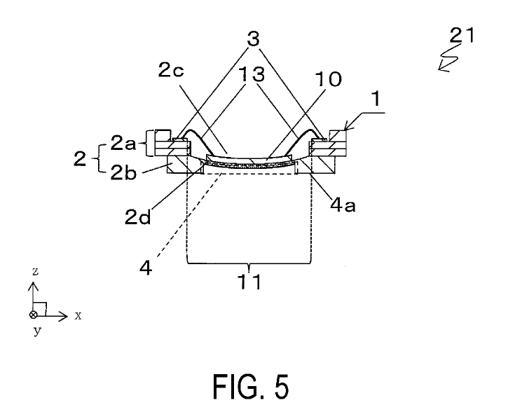

The electronic component mounting package 1 and the electronic device 21 according to a fourth embodiment of the present invention will be described next with reference to FIG. 5.

In the electronic device 21 according to the present embodiment, a point of difference with the electronic device 21 according to the second embodiment is that the thickness between the recessed portion 2d and the notch 4 is smaller.

As illustrated in the example in FIG. 5, by making the thickness between the recessed portion 2d and the notch 4 of the electronic component mounting package 1 smaller, the volume directly below the curved electronic component mounting portion 11 becomes smaller. As a result, since the heat radiating properties can be made even smaller, when the curved electronic component 10 operates and generates heat, the stress of the thermal expansion can be made smaller. Thus, the stress acting on the boundary between the curved electronic component mounting portion 11 and the flat portion 11a surrounding the curved electronic component mounting portion 11 can be reduced, and deformation, cracks, or breaks of the substrate 2 can be further reduced.

In addition, in the example illustrated in FIG. 5, the outer peripheral portion of the base portion 2b is positioned further to the inner side than the outer peripheral portion of the frame body 2a in a plan view. In this way, in the step of bonding the frame body 2a and the base portion 2b, even if the bonding position of the base portion 2b is displaced due to step displacement, there is no possibility that the base portion 2b will be positioned further to the outer side than the outer peripheral portion of the frame body 2a in a plan view. Thus, the electronic device 21 can be downsized.

### Fifth Embodiment

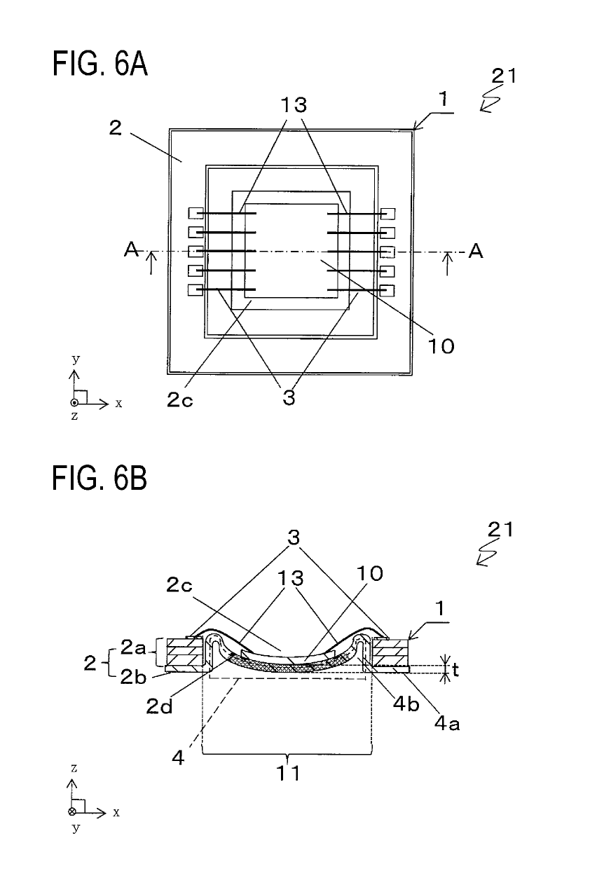

The electronic component mounting package 1 and the electronic device 21 according to a fifth embodiment of the present invention will be described next with reference to FIGS. 6A and 6B.

In the electronic device 21 according to the present embodiment, points of difference with the electronic device 21 according to the second embodiment are that the shape of the recessed portion 2d is different and the shape of the notch 4 is different.

In an example illustrated in FIGS. 6A and 6B, the substrate 2 has the frame body 2a and the base portion 2b provided on the bottom surface of the frame body 2a. In a cross-sectional view, an outer peripheral portion of the notch 4 has a protruding portion 4b that is protrudes to a position higher than a bonded portion between the frame body 2a and the base portion 2b. Since the notch 4 has the protruding portion 4b, the base portion 2b has an elastic structure between the flat portion 11a and the recessed portion 2d. Since the base portion 2b has the elastic structure between the flat portion 11a and the recessed portion 2d, when the curved electronic component 10 operates and generates heat, the stress of the thermal expansion can be absorbed by the elastic structure. Thus, the stress acting on the boundary between the curved electronic component mounting portion 11 and the flat portion 11a surrounding the curved electronic component mounting portion 11 can be reduced, and deformation, cracks, or breaks of the substrate 2 can be further reduced. Note that the material of the base portion 2b having the present structure may be one of the electrical insulating ceramic, the resin and the like, but more effects can be obtained if the base portion 2b is made from a metal material having high ductility.

### Sixth Embodiment

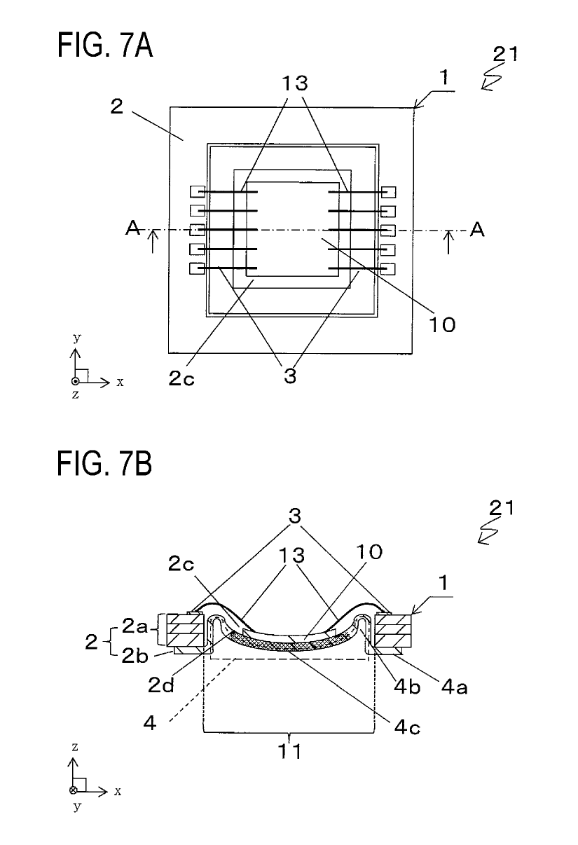

The electronic component mounting package 1 and the electronic device 21 according to a sixth embodiment of the present invention will be described next with reference to FIGS. 7A and 7B.

In the electronic device 21 according to the present embodiment, a point of difference with the electronic device 21 according to the fifth embodiment is that the lowest point 4c of the notch 4 in a vertical cross-sectional view is higher than the bottom surface of the substrate 2.

In an example illustrated in FIGS. 7A and 7B, in the electronic component mounting package 1, the lowest point 4c of the notch 4 is higher than the bottom surface of the substrate 2 in a vertical cross-sectional view. As a result of this, when the electronic device 21 using the electronic component mounting package 1 of the present embodiment is mounted on an external circuit, contact between the external circuit and the inner face of the notch 4 can be reduced. Thus, when the curved electronic component 10 operates and generates heat, since rubbing of the base portion 2b against the external circuit can be reduced, the occurrence of dust and the like can be reduced.

Further, in the example illustrated in FIGS. 7A and 7B, the thickness between first main surfaces of the protruding portion 4b and the base portion 2b in a cross-sectional view is thinner than at other locations. As a result of this, in the base portion 2b, the effect of elasticity between the flat portion 11a and the recessed portion 2d can be further improved. Thus, when the curved electronic component 10 operates and generates heat, the stress of the thermal expansion can be absorbed by the elastic structure. Further, the stress acting on the boundary between the curved electronic component mounting portion 11 and the flat portion 11a surrounding the curved electronic component mounting portion 11 can be reduced, and deformation, cracks, or breaks of the substrate 2 can be further reduced.

Note further that, in the same manner as illustrated in FIGS. 1A and 1B, the lowest point 4c of the notch 4 is a section of the inner surface (the bottom surface) of the notch 4 that is closest to the bottom surface side of the substrate 2.

### Seventh Embodiment

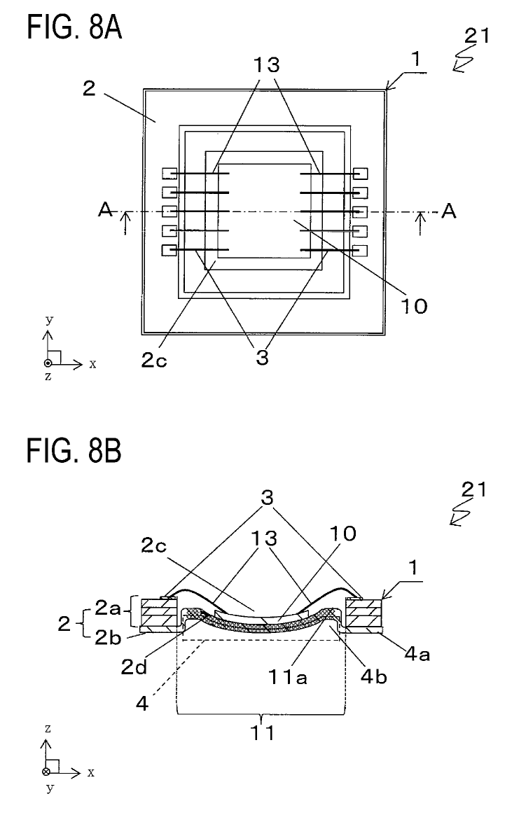

The electronic component mounting package 1 and the electronic device 21 according to a seventh embodiment of the present invention will be described next with reference to FIGS. 8A and 8B.

In the electronic device 21 according to the present embodiment, a point of difference with the electronic device 21 according to the fifth embodiment is that the flat portion 11a is provided around the periphery of the recessed portion 2d of the base portion 2b.

In an example illustrated in FIGS. 8A and 8B, the flat portion 11a is provided around the periphery of the recessed portion 2d of the base portion 2b of the electronic component mounting package 1. In this way, the volume of the periphery of the recessed portion 2d of the base portion 2b can be enlarged. Thus, for example, the heat generated by the signal processing portion 10a provided on the outer peripheral portion of the curved electronic component 10 can be conducted to the flat portion 11a, and the heat transmitted to other locations of the curved electronic component 10 can be reduced. As a result, the heat distribution in the other locations of the curved electronic component 10 can be made constant at an even lower temperature.

### Eighth Embodiment

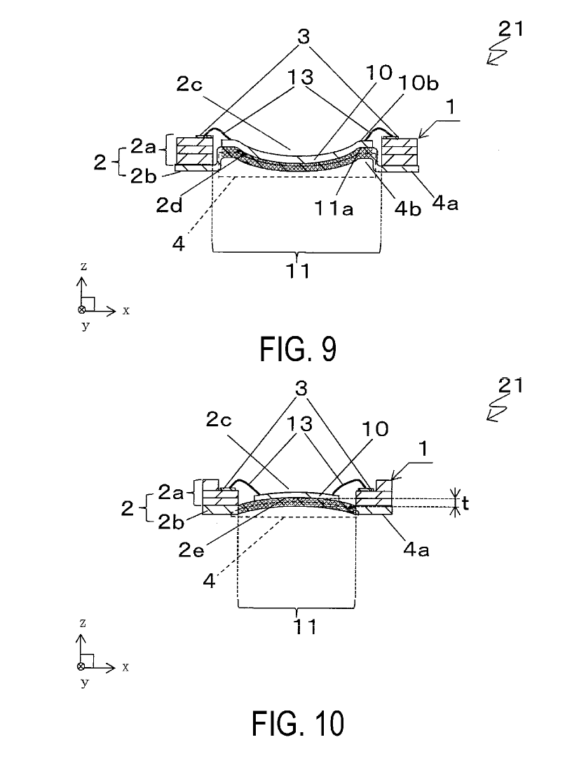

The electronic component mounting package 1 and the electronic device 21 according to an eighth embodiment of the present invention will be described next with reference to FIG. 9.

In the electronic device 21 according to the present embodiment, a point of difference with the electronic device 21 according to the seventh embodiment is that the curved electronic component 10 has a flat region 10b, and the flat region 10b is positioned in a section that overlaps, in a plan view, with the flat portion 11a of the base portion 2b.

In the example illustrated in FIGS. 8A and 8B, the curved electronic component 10 has the flat region 10b, and the flat region 10b is positioned in a section that overlaps, in a plan view, with the flat portion 11a of the base portion 2b.

In general, in a step in which the curved electronic components 10 are divided into individual pieces in a dicing step and the like, or in a step of transportation or the like, origins of minute cracks may occur in the outer peripheral portion thereof. Therefore, in the step in which the curved electronic component 10 is mounted in the recessed portion 2d, if stress is applied to the curved electronic component 10, cracks can be generated from the origins of those minute cracks. Thus, when the curved electronic component 10 has the flat region 10b, and the flat region 10b is positioned in the section that overlaps, in a plan view, with the flat portion 11a of the base portion 2b, as in the present configuration, the stress applied to the outer peripheral portion of the curved electronic component 10 can be reduced. As a result, the generation of the cracks from the origins of the minute cracks in the outer peripheral portion of the curved electronic component 10 can be reduced.

Further, when the curved electronic component 10 has the flat region 10b, the connecting members 13 are provided in the flat region 10b, and thus, in a wire bonding step, a more favorable connection can be obtained.

In the examples illustrated in FIGS. 6A to 9, the shape of the peripheral edge of the recessed portion 2d may be the rectangular shape in a plan view, but may also be a circular shape in a plan view. Further, when the shape of the peripheral edge of the recessed portion 2d has one or more corner portions in a plan view, by causing each of edges connecting the corner portions not to be a straight line but to draw a gently curved line, the stress acting on the curved electronic component 10 when mounting the curved electronic component 10 can be reduced.

Further, in the examples illustrated in FIGS. 6A to 9, the angle θ formed between the side surfaces of the recessed portion 2d and extended surfaces of the flat portion 11a provided around the recessed portion 2d is less than 90°.

Further, in the examples illustrated in FIGS. 6A to 9, the thickness t of the curved electronic component mounting portion 11 that overlaps with the notch 4 in a plan view is 50 μm or greater. This is favorable in that a rise in the temperature of the substrate 2 directly below the curved electronic component mounting portion 11 is suppressed, while the heat distribution of the curved electronic component mounting portion 11 is easily made uniform. Furthermore, when the curved electronic component 10 is the imaging device, a curvature of the recessed portion 2d is preferably equal to or less than the curvature of the convex lens or the concave lens provided on the bottom-most surface side of the lens housing that is bonded to the electronic device 21. Since the curvature of the recessed portion 2d is equal to the curvature of the concave lens or the convex lens provided on the bottom-most surface side of the lens housing, a more favorable image can be obtained. Further, since the curvature of the recessed portion 2d is equal to or less than the curvature of the concave lens or the convex lens provided on the bottom-most surface side of the lens housing, in the step of mounting the curved electronic component 10, bonding can be performed without placing any load on the curved electronic component 10.

### Ninth Embodiment

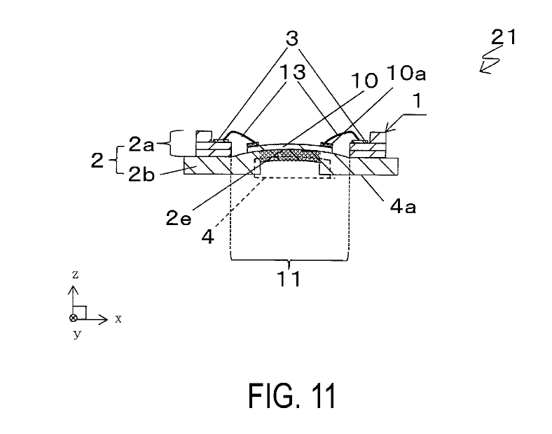

The electronic component mounting package 1 and the electronic device 21 according to a ninth embodiment of the present invention will be described next with reference to FIGS. 10 and 11.

In the electronic device 21 according to the present embodiment, a point of difference with the electronic device 21 according to the first embodiment is that the electronic component mounting package 1 has an arc-shaped convex portion 2e in palace of the arc-shaped recessed portion 2d.

In the examples illustrated in FIGS. 10 and 11, the electronic component mounting package 1 includes: the substrate 2 including the first main surface and the second main surface, and the convex portion 2e, that is provided in the first main surface and is arc-shaped in a vertical cross-sectional view; and a curved electronic component mounting portion 11, which is provided in the convex portion 2e and on which the bent curved electronic component 10 is mounted. The substrate 2 has the notch 4 in the second main surface such that the notch 4 overlaps with the curved electronic component mounting portion 11 when the substrate 2 is seen in a plane perspective from the first main surface side. Therefore, when, in a similar manner to the first embodiment, the curved electronic component 10 is mounted in the electronic component mounting package 1, and the curved electronic component 10 operates and generates heat, by having the notch, the thickness of the substrate 2 can be made appropriate in accordance with the heat generation location of the curved electronic component 10. Thus, the heat radiation of the curved electronic component 10 can be optimized, and the heat distribution of the curved electronic component mounting portion 11 can be made uniform.

Further, even when the thermal expansion or the thermal shrinkage of the electronic component mounting package 1 occurs when the curved electronic component 10 operates and generates heat, the stress of the thermal expansion or the thermal shrinkage from the curved electronic component mounting portion 11 can be alleviated and absorbed. Thus, the stress acting on the boundary between the curved electronic component mounting portion 11 and the flat portion 11a surrounding the curved electronic component mounting portion 11 can be reduced, and deformation, cracks, or breaks of the substrate 2 can be reduced.

Further, in a cross-sectional view, a distance from a peripheral edge of the convex portion 2e of the substrate 2 to a highest point of the convex portion 2e is preferably 30 μm or greater. Since, in a cross-sectional view, the distance from the peripheral edge of the convex portion 2e of the substrate 2 to the highest point of the convex portion 2e is 30 μm or greater, in the step of mounting the curved electronic component 10, the curved electronic component 10 is easily mounted in the center of the recessed portion 2d. Furthermore, when the curved electronic component 10 is the imaging device, a curvature of the convex portion 2e is preferably equal to or greater than the curvature of the convex lens provided on the bottom-most surface side of the lens housing that is bonded to the electronic device 21. When the curvature of the convex portion 2e is equal to the curvature of the convex lens provided on the bottom-most surface side of the lens housing, a more favorable image can be obtained. Further, when the curvature of the recessed portion 2d is greater than the curvature of the convex lens provided on the bottom-most surface side of the lens housing, in the step of mounting the curved electronic component 10, bonding can be performed without placing any load on the curved electronic component 10.

Further, the angle θ formed between the side surfaces of the convex portion 2e and the extended surfaces of the flat portion 11a provided around the recessed portion 2d is less than 90°.

In an example illustrated in FIG. 11, the signal processing portion 10a is provided on the outer peripheral portion of the curved electronic component 10, and the notch 4 is provided in a position that does not overlap with the signal processing portion 10a in a plan view. Therefore, the thickness of the substrate 2 directly below the signal processing portion 10a in a cross-sectional view can be made larger in comparison to the thickness of other portions of the substrate 2, which have a relatively small calorific value. As a result, the heat radiating properties of the signal processing portion 10a can be improved. Further, since the heat radiating properties of the signal processing portion 10a can be improved, the heat generated by the signal processing portion 10a is less easily transmitted to other locations of the curved electronic component 10, and thus the heat distribution in the other locations of the curved electronic component 10 can be more effectively made uniform.

The present invention is not intended to be limited to the examples described in the above-described embodiments, and many variations, such as to numerical values and the like, can be made thereon.

Further, for example, in the examples illustrated in FIGS. 1A to 11, the shape of each of the curved electronic component connection pads 3 is a rectangular shape, but they may be a circular shape or another polygonal shape.

The arrangement, numbers, shapes, and the like of the electronic element connection pads 3 in the above-described embodiments are not specified.

In addition, various combinations of characteristic portions of the above-described embodiments are not limited to the examples in the above-described embodiments.

Further, the shape of the curved electronic component 10 illustrated in FIGS. 1A to 11 may be any shape. For example, the curved electronic component 10 mounted according to the first embodiment may be provided with the flat region 10b, and according to the first embodiment, for example, the substrate 2 may have the convex portion 2e.

1. An electronic component mounting package comprising:
a substrate comprising
a first main surface having one of a recessed portion and convex portion that is arc-shaped in a vertical cross-sectional view, and a curved electronic component mounting portion, which is provided in the one of the recessed portion and the convex portion, on which a bent curved electronic component is mounted; and
a second main surface having a notch, the notch overlapping with the curved electronic component mounting portion when the substrate is seen in a plane perspective from the first main surface side.

2. The electronic component mounting package according to claim 1, wherein
the substrate has a constant thickness between the notch and the one of the recessed portion and the convex portion.

3. The electronic component mounting package according to claim 1, wherein,
when seen in a plane perspective from the first main surface side, the substrate has a constant thickness between one of the recessed portion and the convex portion overlapping with the notch and the notch.

4. The electronic component mounting package according to claim 1, wherein
a lowest point of the notch is positioned at the same height as the second main surface of the substrate in a vertical cross-sectional view.

5. The electronic component mounting package according to claim 1, wherein
the substrate includes a frame body and a base portion comprised the notch provided on the second main surface the frame body, and
an outer peripheral portion of the notch includes a protruding portion that protrudes, in a cross-sectional view, to a position higher than a bonded portion between the frame body and the base portion.

6. The electronic component mounting package according to claim 5, wherein
a top surface of the protruding portion includes a flat section.

7. An electronic device comprising:
the electronic component mounting package according to claim 1; and
the curved electronic component mounted in the electronic component mounting package.

8. The electronic device according to claim 7, wherein
a signal processing portion is provided on an outer peripheral portion of the curved electronic component, and wherein the notch does not overlap with the signal processing portion in a plan view.

9. An electronic component mounting package comprising:
a substrate having a first main surface and a second main surface,
wherein the first main surface has an arc-shaped portion, and the second main surface has a notch portion opposite the arc-shaped portion, and
wherein the electronic component is mounted on the arc-shaped portion.
